(19) United States
(12) Patent Application Publication
(10) Pub. No.: US 2013/0221390 A1
(43) Pub. Date: Aug. 29, 2013

(54) LIGHT-EMITTING DIODE CHIP

(71) Applicants: Karl Engl, Pentling (DE); Markus Maute, Alteglofsheim (DE); Stefanie Rammelsberger, Zeitlarn (DE)

(72) Inventors: Karl Engl, Pentling (DE); Markus Maute, Alteglofsheim (DE); Stefanie Rammelsberger, Zeitlarn (DE)

(73) Assignee: OSRAM OPTO SEMICONDUCTORS GMBH, Regensburg (DE)

(21) Appl. No.: 13/820,306

(22) PCT Filed: Aug. 24, 2011
(86) PCT No.: PCT/EP2011/064556

§ 371 Date: May 6, 2013

(30) Foreign Application Priority Data
Sep. 3, 2010 (DE) 10 2010 036 269.7

(51) Int. Cl. H01L 33/46

(52) U.S. Cl. CPC H01L 33/46
USPC 257/98

(57) ABSTRACT

A light-emitting diode chip having a semiconductor layer sequence having an active layer that generates electromagnetic radiation, wherein the light-emitting diode chip has, on a front side, a radiation exit surface, at least regions of the light-emitting diode chip have, on a rear side opposite the radiation exit surface, a mirror layer containing silver, a protective layer containing Pt is disposed on the mirror layer, and the protective layer has a structure that covers the mirror layer only in sub-regions.

### RELATED APPLICATIONS

This application is a §371 of International Application No. PCT/EP2011/064556, with an international filing date of Aug. 24, 2011 (WO 2012/028513 A1, published Mar. 8, 2012), which claims priority of German Patent Application No. 10 2010 036 269.7, filed Sep. 3, 2010, the subject matter of which is hereby incorporated by reference.

### TECHNICAL FIELD

This disclosure relates to a light-emitting diode chip.

### BACKGROUND

So-called “thin-film light-emitting diode chips” are known in which the original growth substrate of the semiconductor layer sequence is detached and, instead, the semiconductor layer sequence connects to a carrier substrate on a side opposite to the original growth substrate by a solder layer. In that case, the radiation exit surface of the light-emitting diode chip is disposed on a surface of the semiconductor layer sequence opposite to the carrier substrate, i.e., on the side of the original growth substrate. In the case of a light-emitting diode chip of that type, it is advantageous if the side of the semiconductor layer sequence facing towards the carrier substrate is provided with a mirror layer to divert radiation emitted in the direction of the carrier, in the direction of the radiation exit surface and thereby to increase radiation yield.

For the visible spectral range, a material which is suitable for the mirror layer is in particular silver. Silver is characterized by high reflection in the visible spectral range and suitable to establish a good electrical contact to the semiconductor material. However, on the other hand, silver is susceptible to corrosion and migration of the silver into adjacent layers can occur.

A protective layer is generally applied to the silver layer to protect a mirror layer consisting of silver against corrosion. In particular, a platinum layer is suitable as the protective layer. However, it has turned out to be the case that reflection of the boundary surface between the mirror layer and the semiconductor layer sequence can be impaired by application of a protective layer consisting of platinum to the boundary surface of the mirror layer opposite to the semiconductor layer sequence. As a result, the coupling-out of light and thus the efficiency of the light-emitting diode chip are reduced. This effect is possibly based upon the fact that, at the process temperatures typical for the application of the layers, the platinum can penetrate into the silver layer and even travel as far as to the opposite boundary surface between the mirror layer and the semiconductor layer.

It could therefore be helpful to provide a light-emitting diode chip having a mirror layer on the rear side protected against corrosion by a protective layer, wherein at the same time, however, reflection of the boundary surface between the silver layer and the semiconductor layer sequence is only slightly impaired.

### SUMMARY

We provide a light-emitting diode chip including a semiconductor layer sequence having an active layer that generates electromagnetic radiation, wherein the light-emitting diode chip has, on a front side, a radiation exit surface, at least regions of the light-emitting diode chip have, on a rear side opposite the radiation exit surface, a mirror layer containing silver, a protective layer containing Pt is disposed on the mirror layer, and the protective layer has a structure that covers the mirror layer only in sub-regions.

We also provide a light-emitting diode chip including a semiconductor layer sequence having an active layer that generates electromagnetic radiation, wherein the light-emitting diode chip has, on a front side, a radiation exit surface, at least regions of the light-emitting diode chip have, on a rear side opposite the radiation exit surface, a mirror layer containing silver, a protective layer containing Pt is disposed on the mirror layer, and the protective layer has a structure that covers the mirror layer only in sub-regions, and the protective layer has a plurality of mutually spaced apart sub-regions, wherein a spaced interval between adjacent sub-regions is on average 2 μm to 20 μm, or the protective layer has a plurality of openings, the openings having on average a lateral dimension of 2 μm to 20 μm.

### BRIEF DESCRIPTION OF THE DRAWINGS

FIG. 1A shows a schematic illustration of a cross-section of a light-emitting diode chip according to a first example along the line AB of the top view illustrated in FIG. 1B.

FIG. 1B shows a top view of the mirror layer, which is provided with a structured protective layer, of the example of a light-emitting diode chip illustrated in FIG. 1A.

FIG. 2 shows a schematic illustration of a top view of the mirror layer provided with a protective layer in the case of a light-emitting diode chip according to a further example.

FIG. 3 shows a schematic illustration of a top view of the mirror layer provided with a protective layer in the case of a light-emitting diode chip according to a further example.

FIG. 4 shows a schematic illustration of a cross-section of a light-emitting diode chip according to a further example.

### DETAILED DESCRIPTION

Our light-emitting diode chip may contain a semiconductor layer sequence which has an active layer suitable to generate electromagnetic radiation. The light-emitting diode chip has, on a front side, a radiation exit surface through which the electromagnetic radiation emitted by the active layer exits the semiconductor layer sequence. The front side of the light-emitting diode chip is understood to be the side of the light-emitting diode chip on which the radiation exit surface is disposed.

On a rear side opposite the radiation exit surface, at least regions of the light-emitting diode chip have a mirror layer which contains silver.

A protective layer that reduces corrosion of the mirror layer is disposed on the mirror layer. The protective layer advantageously contains or consists of Pt.

The protective layer advantageously has a structure such that it covers the mirror layer only in sub-regions. The protective layer is thus structured such that it does not cover in particular the entire surface of the mirror layer. The mirror layer thus has sub-regions not covered by the protective layer.

By virtue of the fact that the entire surface of the mirror layer is not covered by the protective layer, diffusion of constituents of the protective layer into the mirror layer is reduced. In particular, by virtue of the fact that the protective layer covers the mirror layer only in sub-regions, diffusion of Pt into the mirror layer and/or as far as to the boundary surface between the mirror layer and the semiconductor layer sequence is reduced in comparison with a protective layer applied over the entire surface. In this manner, reflection of the boundary surface between the semiconductor layer sequence and the mirror layer is advantageously increased, whereby the coupling-out of light of the light-emitting diode chip is improved and efficiency is thus increased.

We surprisingly found that a protective layer consisting of Pt can even function as a protective layer for a silver-containing mirror layer if it does not cover the mirror layer completely, but rather covers it only in sub-regions.

There are several possible explanations for this effect. On the one hand, it is feasible that the material of the protective layer penetrates from the sub-regions, which cover the mirror layer, into the mirror layer where it diffuses preferably along the silver grain boundaries. This could contribute to stabilization of the material of the mirror layer since corrosion effects generally occur on the metallic grain boundaries. Furthermore, it is feasible that the material of the protective layer modifies the occurring electrical potentials in accordance with its position in the electrochemical series such that corrosion effects are suppressed. Furthermore, it is also possible that a different property of the material of the protective layer, which penetrates at least partially into the mirror layer, such as, e.g., an effect as a catalyst or the storage of hydrogen, has a positive influence upon resistance of the mirror layer. By reason of the aforementioned possible effects, a protective effect for the mirror layer is achieved even if the applied protective layer does not cover the surface of the mirror layer completely.

The surface proportion of the mirror layer covered by the protective layer may be 10% to 70%. Particularly preferably, the cover layer covers a surface proportion of 30% to 50% of the mirror layer. In this manner, an effective compromise is achieved between the protective effect of the protective layer to protect the mirror layer against corrosion and reduction in reflection, which is caused by the at least partial penetration of the material of the protective layer into the mirror layer, at the boundary surface between the semiconductor material and the mirror layer. In particular, it has turned out to be the case that with a surface proportion of the protective layer on the mirror layer of 10% to 70% and preferably of 30% to 50%, it is possible to achieve a mirror layer which is substantially stable against corrosion with merely a small reduction in the reflection of the mirror layer in comparison with a mirror layer without a protective layer consisting of Pt.

The protective layer preferably has a thickness of 1 nm to 200 nm, particularly preferably 10 nm to 40 nm.

The protective layer can be configured such that it has a plurality of mutually spaced apart sub-regions. The sub-regions can be distributed uniformly or non-uniformly on the boundary surface of the mirror layer facing away from the semiconductor layer sequence. It is advantageous if, on the one hand, the spaced intervals between the adjacent sub-regions of the protective layer are not too large so that the protective layer has an adequate protective effect for the mirror layer. On the other hand, the spaced intervals should also not be too small. Otherwise, as in the case of a complete coverage of the mirror layer, a not insignificant reduction in reflection occurs on account of penetration of the material of the protective layer into the mirror layer. It is particularly advantageous if a spaced interval between adjacent sub-regions is on average 2 μm to 20 μm. The spaced interval is understood to be the shortest distance between the edges of adjacent sub-regions.

Alternatively, the protective layer has a plurality of openings, wherein the protective layer provided with the openings forms one or several contiguous structures on the surface of the mirror layer. For example, it is possible that the protective layer is applied initially to the entire surface of the mirror layer and, subsequently, a plurality of openings are produced in the protective layer. Structuring of the protective layer can be effected in particular by photolithography. The openings preferably have on average a lateral dimension of 2 μm to 20 μm.

The protective layer may have a lattice structure having several lines and columns. In particular, the lattice structure can be a rectangular lattice structure. In this case, the protective layer may form a strip pattern on the boundary surface of the mirror layer, wherein the strips extend preferably in two mutually perpendicular directions over the boundary surface of the mirror layer.

The widths of the lines and columns of the lattice structure are preferably 2 μm to 20 μm in each case.

Furthermore, it is advantageous if the spaced intervals between the lines and columns are 2 μm to 20 μm in each case. In this case, the lattice structure serves to form openings in the protective layer, whose lateral dimension is 2 μm to 20 μm in each case.

The protective layer may have an edge web which is circumferential with respect to the edge of the mirror layer. In this edge region, the protective layer is thus preferably not interrupted by openings. This is advantageous, as the mirror layer is at risk of corrosion particularly at its side edges.

A boundary surface of the mirror layer opposite to the protective layer preferably adjoins the semiconductor layer sequence. Therefore, between the semiconductor layer sequence and the mirror layer there is no intermediate layer, such as, e.g., an adhesion promoter layer, which could lead to a reduction in reflection at the boundary surface between the mirror layer and the semiconductor layer sequence. Rather, it has turned out to be the case that the properties desired for the mirror layer, namely good adhesion on the semiconductor material, good electrical connection to the semiconductor material and protection against corrosion and migration of silver, can be achieved by a protective layer applied in a structured manner to a side of the mirror layer opposite the semiconductor layer sequence. The mirror layer can adjoin in particular a p-type semiconductor region of the semiconductor layer sequence.

The light-emitting diode chip connects to a carrier substrate preferably on a side which as seen from the mirror layer is opposite the semiconductor layer sequence. The carrier substrate is in particular a substrate different from a growth substrate of the semiconductor layer sequence and connects to the semiconductor layer sequence, e.g., by a solder layer.

A growth substrate used for epitaxial growth of the semiconductor layer sequence is preferably detached from the light-emitting diode chip. Therefore, the light-emitting diode chip preferably does not have a growth substrate. By virtue of the fact that the growth substrate is detached from the light-emitting diode chip and the radiation emitted in the direction of the carrier substrate is reflected by the mirror layer towards the radiation coupling-out surface, a light-emitting diode chip having a high level of efficiency is achieved.

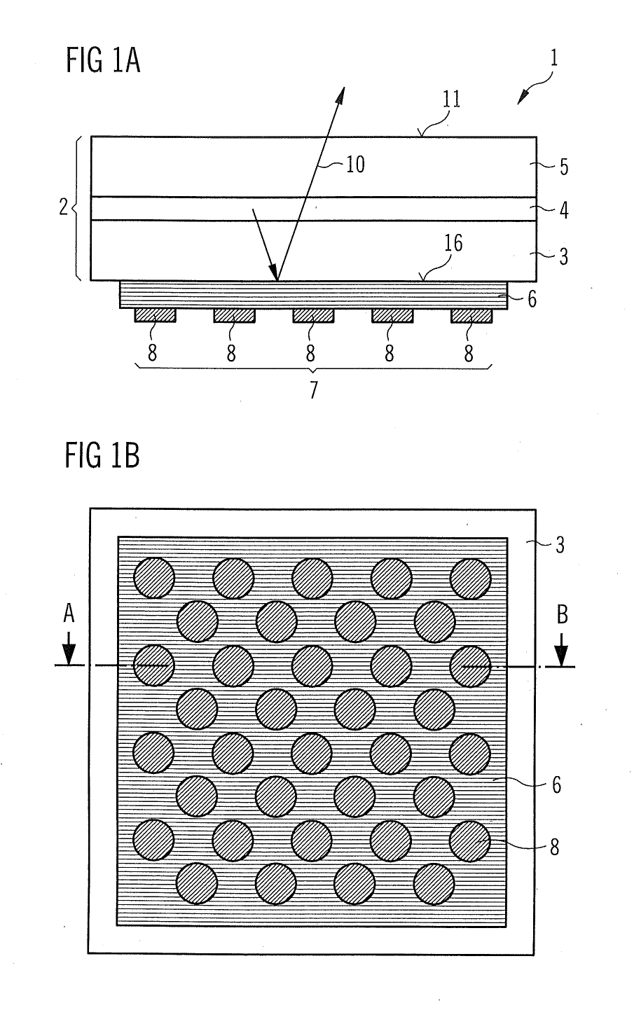

Our chip will be explained in greater detail with reference to examples in conjunction with FIGS. 1 to 4.

Like parts, or parts acting in an identical manner, are provided with the same reference numerals in each case in the figures. The illustrated parts and the size ratios of the parts with respect to each other are not to be regarded as being to scale.

The light-emitting diode chip 1 illustrated in FIG. 1B in a view from below and illustrated in FIG. 1A in a cross-section along the line AB shown in FIG. 1B contains a semiconductor layer sequence 2 which has a first semiconductor region 3 of a first conductivity type and a second semiconductor region 5 of a second conductivity type. Preferably, the first semiconductor region 3 is a p-type semiconductor region and the second semiconductor region 5 is an n-type semiconductor region. An active zone 4 is disposed between the first semiconductor region 3 and the second semiconductor region 5.

The active zone 4 of the light-emitting diode chip 1 can be formed, e.g., as a pn junction, as a double heterostructure, as a single quantum well structure or multiple quantum well structure. The term “quantum well structure” thereby includes any structure in which charge carriers undergo quantization of their energy states by confinement. In particular, the term quantum well structure does not include any information relating to the dimensionality of the quantization. It thus includes inter alia quantum wells, quantum wires and quantum dots and any combination of these structures.

The semiconductor layer sequence 2 can be based in particular upon a nitride compound semiconductor. The phrase “based upon a nitride compound semiconductor” means that the semiconductor layer sequence 2 or at least a layer thereof comprises a III-nitride compound semiconductor material, preferably InₓAl_{y}Ga_{1-x-y}N, wherein 0≦x≦1, 0≦y≦1 and x+y≦1. This material does not necessarily have to be a mathematically exact composition of the above formula. Rather, it can have one or several dopants and additional constituents which do not substantially change the characteristic physical properties of the InₓAl_{y}Ga_{1-x-y}N-material. However, for the sake of simplicity, the above formula includes only essential constituents of the crystal lattice (In, Al, Ga, N), even if they can be replaced in part by small quantities of further substances.

The light-emitting diode chip 1 emits electromagnetic radiation 10 through a radiation exit surface 11 disposed on the front side of the light-emitting diode chip 1. The radiation exit surface 11 can be provided with a surface roughening or a coupling-out structure (not illustrated) to improve the coupling-out of radiation.

Regions of the light-emitting diode chip 1 have a mirror layer 6 on a rear side opposite to the radiation exit surface 11 to improve the efficiency of the light-emitting diode chip 1. Advantageously, radiation emitted by the active layer 4 towards the rear side of the light-emitting diode chip 1 is diverted towards the radiation exit surface 11 by the mirror layer 6.

The mirror layer 6 advantageously contains or consists of silver. A mirror layer consisting of silver advantageously has high reflection in the visible spectral range. Furthermore, silver is characterized by high electrical conductivity. The mirror layer 6 can adjoin in particular the first semiconductor region 3, in particular a p-type semiconductor region, and can form one of the electrical connections of the semiconductor layer sequence 2 of the light-emitting diode chip 1.

A mirror layer 6 consisting of silver can give rise to the problem that it is comparatively susceptible to corrosion, which particularly after a long operation period of the light-emitting diode chip 1, could lead to a reduction in radiation yield. A protective layer 7 is disposed on the boundary surface 16 of the mirror layer 6 facing away from the semiconductor layer sequence 2 to protect the mirror layer 6 against corrosion. The protective layer 7 preferably contains or consists of Pt. The platinum-containing protective layer 7 is characterized by the fact that it is chemically inert and thus protects the mirror layer 6 against corrosion.

The protective layer 7 is structured such that it covers the mirror layer 6 only in sub-regions 8. The mirror layer 6 is in particular not completely covered by the protective layer 7. As can be seen in the top view of the mirror layer 6 in FIG. 1B, the protective layer is structured, e.g., such that it has a plurality of mutually spaced apart sub-regions 8. In the case of the illustrated example, the protective layer 7 is formed by a plurality of circular sub-regions 8. However, the sub-regions 8 of the protective layer 7 can alternatively also assume other uniform or non-uniform shapes. Equally, the arrangement of the sub-regions 8 on the surface of the mirror layer 6 can also be uniform or non-uniform.

It has turned out to be advantageous that the protective layer 7 protects the mirror layer 6 against corrosion even if it covers the mirror layer 6 only partially. This effect can be based in particular upon the fact that the material of the protective layer 7 diffuses partially into the mirror layer 6, wherein it diffuses in particular along the silver grain boundaries of the mirror layer 6 and in this manner prevents corrosion which typically begins at the grain boundaries.

Partial diffusion of the material of the protective layer 7 into the mirror layer 6 can have a disadvantageous effect upon the reflectivity of the mirror layer 6 at the boundary surface 16 to the semiconductor layer sequence 2, in particular if the material of the protective layer 7 passes as far as to the boundary surface 16. A reduction in reflection at the boundary surface 16 between the semiconductor layer sequence 2 and the mirror layer 6 can be reduced by virtue of the fact that the protective layer 7 is applied only to sub-regions of the mirror layer 6. By virtue of the fact that the protective layer 7 is applied only to sub-regions of the mirror layer 6, it is possible to find a good compromise between adequate protection of the mirror layer 6 against corrosion on the one hand, and high reflectivity of the boundary surface 16 between the semiconductor layer sequence 2 and the mirror layer 6 on the other hand.

In particular, comparatively high reflection and good protection of the mirror layer 6 against corrosion can be achieved at the same time if the protective layer 7 covers a surface proportion of 10% to 70% of the mirror layer 6. It is particularly advantageous if the protective layer 7 covers a surface proportion of 30% to 50% of the mirror layer 6.

The thickness of the protective layer is advantageously 1 nm to 200 nm, particularly preferably 10 nm to 40 nm.

The spaced interval between the mutually spaced apart sub-regions 8 of the protective layer 7 is preferably on average 2 μm to 20 μm.

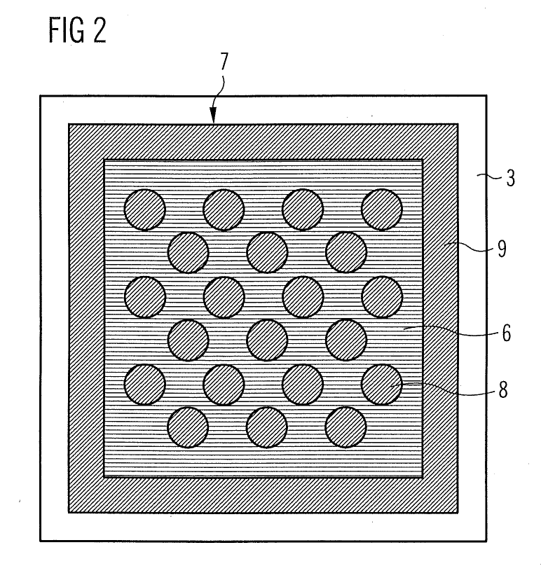

FIG. 2 illustrates a top view of the mirror layer 6 provided with the protective layer 7 in a further example of the light-emitting diode chip 1. The example differs from the example illustrated in FIG. 1 by virtue of the fact that the protective layer 7 has an edge web 9 which is circumferential with respect to the edge of the mirror layer 6. In addition, as in the case of the first example, a plurality of mutually spaced apart sub-regions 8 are disposed on the surface of the mirror layer 6. The edge web 9, which is circumferential with respect to the edge of the mirror layer 6, has the advantage that the mirror layer 6 is well protected in its edge region in which the risk of corrosion is particularly high by the coverage with the protective layer 7. In the edge region of the mirror layer 6, the risk of corrosion is increased, as, e.g., moisture can penetrate from the edges of the light-emitting diode chip 1 into these regions.

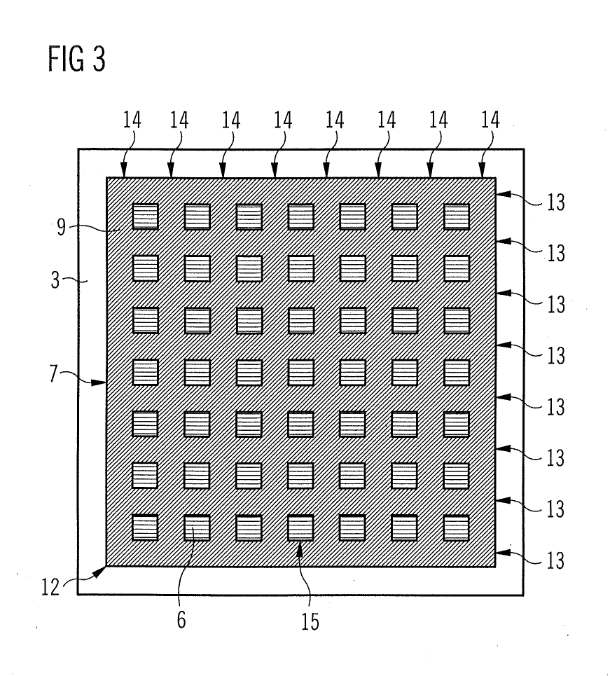

FIG. 3 illustrates a top view of a further example of the mirror layer 6 provided with the protective layer 7. In this example, the protective layer 7 has a lattice structure 12 consisting of a plurality of lines 13 and columns 14 each formed from strip-shaped regions of the protective layer. The lattice structure 12 can be in particular a rectangular lattice structure having uniformly disposed lines 13 and columns 14.

The lines 13 and columns 14 preferably have widths of 2 μm to 20 μm in each case. Furthermore, the spaced intervals between adjacent lines and/or columns is 2 μm to 20 μm in each case. The spaced intervals between the lines or columns is understood to be the spaced interval between the edges of the strips of the protective layer 7 which form the lines or columns. The lattice structure 12 produces on the surface of the mirror layer 6 a plurality of preferably identically large openings 15. The openings 15 preferably have on average a lateral dimension of 2 μm to 20 μm. As in the case of the previously described example, the lattice structure 12 preferably also has an edge web 9 which is circumferential with respect to the edge of the mirror layer 6. This means that the mirror layer 6 is protected in particular against corrosion in its edge region.

The previously described examples of a mirror layer 6 provided with a structured protective layer 7 can be integrated into various configurations of light-emitting diode chips 1 which have a mirror layer 6 on a rear side opposite to the radiation exit surface 11.

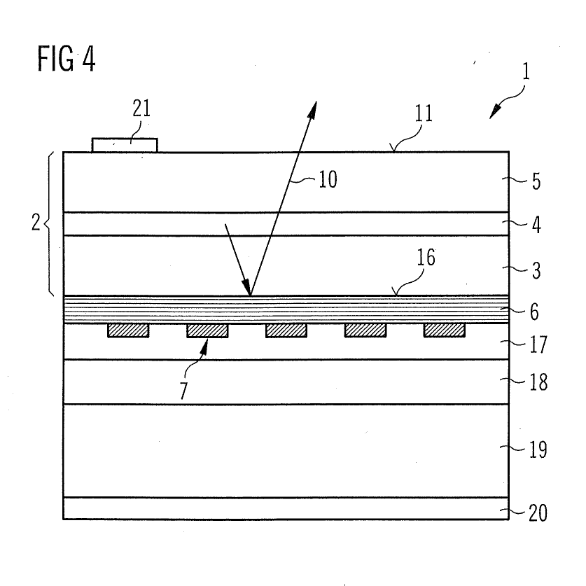

FIG. 4 illustrates a cross-section of an example of a thin-film light-emitting diode chip 1 which has a mirror layer 6 provided with a structured protective layer 7. Like the example illustrated in FIG. 1A, the thin-film light-emitting diode chip 1 has a semiconductor layer sequence 2 having a p-type semiconductor region 3, an n-type semiconductor region 5 and an active zone 4 disposed therebetween. On a rear side opposite the radiation exit surface 11, the light-emitting diode chip 1 connects to a carrier substrate 19, e.g., by a solder layer 18. The light-emitting diode chip 1 does not have a growth substrate. In particular, a growth substrate used for epitaxial growth of the semiconductor layer sequence 2 is detached from the boundary surface of the semiconductor layer sequence 2 now serving as the radiation exit surface 11.

Between the mirror layer 6 provided with the structured protective layer 7 and the solder layer 18, a barrier layer 17 can be disposed which reduces in particular diffusion of parts of the solder layer 18 into the mirror layer 6 and vice versa. The barrier layer 17 can be, e.g., a Ti-layer or a TiW(N)-layer. The barrier layer can also comprise several partial layers (not illustrated), e.g., a Ti/Pt/TiWN-layer sequence. At the same time, the barrier layer 17 can function as a planarization layer for the structured protective layer 7.

The carrier substrate 19 can be, e.g., a silicon or germanium substrate. Electrical contacting of the light-emitting diode chip 1 is effected, e.g., by a first contact layer 20 on the rear side of the carrier substrate and a second contact layer 21 on sub-regions of the surface of the light-emitting diode chip 1. Alternatively, any other arrangements of the contact layers of the light-emitting diode chip 1 are naturally also feasible.

The LED chips described herein are not limited by the description using the examples. Rather, our LED chips include any new feature and any combination of features included in particular in any combination of features in the appended claims, even if the feature or combination itself is not explicitly stated in the claims or examples.

1. A light-emitting diode chip comprising a semiconductor layer sequence having an active layer that generates electromagnetic radiation, wherein
the light-emitting diode chip has, on a front side, a radiation exit surface,
at least regions of the light-emitting diode chip have, on a rear side opposite the radiation exit surface, a mirror layer containing silver,
a protective layer containing Pt is disposed on the mirror layer, and
the protective layer has a structure that covers the mirror layer only in sub-regions.

2. The light-emitting diode chip according to claim 1, wherein the protective layer covers a surface proportion of 10% to 70% of the mirror layer.

3. The light-emitting diode chip according to claim 2, wherein the protective layer covers a surface proportion of 30% to 50% of the mirror layer.

4. The light-emitting diode chip according to claim 1, wherein the protective layer has a thickness of 1 nm to 200 nm.

5. The light-emitting diode chip according to claim 4, wherein the protective layer has a thickness of 10 nm to 40 nm.

6. The light-emitting diode chip according to claim 1, wherein the protective layer has a plurality of mutually spaced apart sub-regions, and a spaced interval between adjacent sub-regions is on average 2 μm 20 μm.

7. The light-emitting diode chip according to claim 1, wherein the protective layer has a plurality of openings, and the openings have on average a lateral dimension of 2 μm to 20 μm.

8. The light-emitting diode chip according to claim 1, wherein the protective layer has a lattice structure having plurality of lines and columns.

9. The light-emitting diode chip according to claim 8, wherein widths of the lines and columns are 2 μm to 20 μm.

10. The light-emitting diode chip according to claim 8, wherein the spaced intervals between the lines and columns are 2 μm to 20 μm.

11. The light-emitting diode chip according to claim 1, wherein the protective layer has an edge web which is circumferential with respect to an edge of the mirror layer.

12. The light-emitting diode chip according to claim 1, wherein the boundary surface of the mirror layer opposite the protective layer adjoins the semiconductor layer sequence.

13. The light-emitting diode chip according to claim 12, wherein a region of the semiconductor layer sequence adjoining the mirror layer is a p-type semiconductor region.

14. The light-emitting diode chip according to claim 1, wherein the light-emitting diode chip connects to a carrier substrate on a side which as seen from the mirror layer is opposite the semiconductor layer sequence.

15. The light-emitting diode chip according to claim 1, wherein the light-emitting diode chip does not have a growth substrate.

16. A light-emitting diode chip comprising a semiconductor layer sequence having an active layer that generates electromagnetic radiation, wherein
the light-emitting diode chip has, on a front side, a radiation exit surface,
at least regions of the light-emitting diode chip have, on a rear side opposite the radiation exit surface, a mirror layer containing silver,
a protective layer containing Pt is disposed on the mirror layer, and
the protective layer has a structure that covers the mirror layer only in sub-regions, and the protective layer has a plurality of mutually spaced apart sub-regions, wherein a spaced interval between adjacent sub-regions is on average 2 μm to 20 μm, or the protective layer has a plurality of openings, the openings having on average a lateral dimension of 2 μm to 20 μm.
